(19) United States
(12) Patent Application Publication
(10) Pub. No.: US 2007/0184568 A1
(43) Pub. Date: Aug. 9, 2007

(54) Method of manufacturing gallium nitride based light emitting diode

(75) Inventors: Dae Yeon Kim, Suwon (KR); Sung Min Hwang, Yongin (KR); Jin Bock Lee, Osan (KR); Sang Ho Yoon, Gunpo (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO, LTD.

(21) Appl. No.: 11/646,406

(22) Filed: Dec. 28, 2006

(30) Foreign Application Priority Data
Feb. 3, 2006 (KR) 10-2006-0010331

(51) Int. Cl. H01L 21/00

(52) U.S. Cl. 438/22; 438/46; 438/47

(57) ABSTRACT

Provided a method of manufacturing a GaN-based LED comprising forming an n-type GaN layer on a substrate; forming an active layer on the n-type GaN layer; forming a p-type GaN layer on the active layer; mesa-etching portions of the p-type GaN layer and the active layer so as to expose a portion of the n-type GaN layer; forming an irregularities forming layer on the p-type GaN layer; forming a photosensitive film pattern for forming a surface irregularities pattern on the irregularities forming layer; selectively wet-etching the irregularities forming layer by using the photosensitive film pattern as an etching mask, thereby forming surface irregularities; forming a p-electrode on the p-type GaN layer having the surface irregularities formed thereon; and forming an n-electrode on the exposed n-type GaN layer.

### CROSS-REFERENCE TO RELATED APPLICATIONS

This application claims the benefit of Korean Patent Application No. 10-2006-0010331 filed with the Korean Intellectual Property Office on Feb. 3, 2006, the disclosure of which is incorporated herein by reference.

### BACKGROUND OF THE INVENTION

1. Field of the Invention

The present invention relates to a method of manufacturing a gallium nitride based light emitting diode (hereinafter, referred to as a GaN-based LED), which can increase light extraction efficiency so as to increase external quantum efficiency and a production yield.

2. Description of the Related Art

In general, a GaN-based semiconductor is such a material that has a relatively high energy band gap (in the case of GaN semiconductor, about 3.4 eV), and is positively adopted in an optical element for generating green or blue short-wavelength light. As such a GaN-based semiconductor, a material having a compositional formula of AlₓIn_{y}Ga_{(1-x-y)}N (herein, 0≦x≦1, 0≦y≦1, and 0≦x+y≦1) is widely used.

Such a GaN-based LED is roughly classified into a lateral GaN-based LED and a vertical GaN-based LED.

However, the conventional GaN-based LED has a problem in efficiency where photon generated from an active layer is emitted to the outside of the LED. That is, the external quantum efficiency is reduced.

FIG. 1 is a diagram for explaining the reduction in external quantum efficiency in a conventional GaN-based LED. Referring to FIG. 1, an incident angle θ₁ at which photon is incident from a GaN layer to the air should be less than a critical angle θ_{c} so that the photon generated from an active layer can pass through the GaN layer having a refractive index N₁ greater than a refractive index N₂ of the air and then escape into the air.

When an escape angle θ₂ at which the photon escapes into the air is 90°, the critical angle θ_{c} is defined as θ_{c}=sin⁻¹ (N₂/N₁). When light propagates from the GaN layer to air having a refractive index of 1, a critical angle is about 23.6°.

When the incident angle θ₁ is greater than the critical angel θ_{c} the photon is totally reflected at an interface between the GaN layer and the air and goes back into the LED. Then, the photon is confined inside the LED, so that the external quantum efficiency is greatly reduced.

To prevent the reduction in the external quantum efficiency, surface irregularities are formed on the surface of a GaN layer, from which light is emitted into the air, thereby reducing an incident angle θ₁ of photon incident to the air from the GaN layer below a critical angle θ_{c}.

In the vertical GaN-based LED, light is emitted into an n-type GaN layer. Accordingly, as shown in FIG. 2, an n-type GaN layer 20 is prepared, and wet-etching is then performed on the top surface of the n-type GaN layer 20, thereby forming surface irregularities. Next, an ITO layer 30 which can enhance current spreading efficiency is formed on the surface irregularities such that the top surface of the ITO layer 30 has the same profile as the surface irregularities.

In the lateral GaN-based LED, light is emitted into a p-type GaN layer. Accordingly, surface irregularities should be formed by performing a wet-etching process on the p-type GaN layer. However, it is difficult to form surface irregularities on the p-type GaN layer through a wet-etching process. Therefore, when the p-type GaN layer 10 is grown, the p-type GaN layer 10 has surface irregularities formed through an MOCVD(Metal Organic Chemical Vapor Deposition) process at the initial stage, as shown in FIG. 3. Then, an ITO layer 30 which can enhance current spreading efficiency is formed on the surface irregularities such that the top surface of the ITO layer 30 has the same profile as the surface irregularities.

The surface irregularities formed on the top surface of the GaN layer, manufactured by the conventional method, should be formed through different processes depending on the type of GaN layer. Therefore, the process of forming surface irregularities becomes complicated.

Further, the surface irregularities formed through the above-described process, that is, the wet-etching process and the MOCVD process has nonuniform concave and convex portions formed on the entire top surface of the GaN layer. Therefore, the improvement of external quantum efficiency, which can be obtained by applying the surface irregularities, is not sufficient.

Therefore, a new technique is being required, which can maximize the improvement of external quantum efficiency.

### SUMMARY OF THE INVENTION

An advantage of the present invention is that a GaN-based LED in which surface irregularities are formed on an irregularities forming layer through a photolithography process, the surface irregularities being formed of TiO₂ having a similar refractive index to the GaN layer and a low absorption rate in the visible ray range. The surface irregularities are formed to have such an appropriate pitch and height that light extraction efficiency can be maximized, thereby enhancing external light emission efficiency and quantum efficiency.

Additional aspect and advantages of the present general inventive concept will be set forth in part in the description which follows and, in part, will be obvious from the description, or may be learned by practice of the general inventive concept.

According to an aspect of the invention, a method of manufacturing a GaN-based LED comprises forming an n-type GaN layer on a substrate; forming an active layer on the n-type GaN layer; forming a p-type GaN layer on the active layer; mesa-etching portions of the p-type GaN layer and the active layer so as to expose a portion of the n-type GaN layer; forming an irregularities forming layer on the p-type GaN layer; forming a photosensitive film pattern for forming a surface irregularities pattern on the irregularities forming layer; selectively wet-etching the irregularities forming layer by using the photosensitive film pattern as an etching mask, thereby forming surface irregularities; forming a p-electrode on the p-type GaN layer having the surface irregularities formed thereon; and forming an n-electrode on the exposed n-type GaN layer.

According to another aspect of the invention, the p-electrode is formed on the p-type GaN layer on which the surface irregularities are not formed.

According to a further aspect of the invention, the method of manufacturing a GaN-based LED further comprises a current spreading layer on the p-type GaN layer before the forming of the irregularities forming layer.

According to a still further aspect of the invention, a method of manufacturing a GaN-based LED comprises sequentially forming an n-type GaN layer, an active layer, a p-type GaN layer on a substrate, thereby forming a GaN-based LED structure; forming a p-electrode on the GaN-based LED structure; bonding a conductive substrate on the p-electrode; removing the substrate through an LLO process so as to expose the n-type GaN layer; forming an irregularities forming layer on the n-type GaN layer which is exposed by removing the substrate; forming a photosensitive film pattern for forming a surface irregularities pattern on the irregularities forming layer; selectively wet-etching the irregularities forming layer by using the photosensitive film pattern as an etching mask, thereby forming surface irregularities; and forming an n-electrode on the n-type GaN layer having the surface irregularities formed thereon.

According to a still further aspect of the invention, the n-type electrode is formed on the n-type GaN layer on which the surface irregularities are not formed.

According to a still further aspect of the invention, the method of manufacturing a GaN-based LED further comprises forming a current spreading layer on the n-type GaN layer before the forming of the irregularities forming layer.

According to a still further aspect of the invention, the irregularities forming layer is formed of TiO₂.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram for explaining such a problem that the external quantum efficiency of a general GaN-based LED is reduced;

FIGS. 2A to 2C are sectional views sequentially showing a method of manufacturing surface irregularities of a conventional GaN-based LED;

FIGS. 3A and 3B are sectional views sequentially showing a method of manufacturing surface irregularities of another conventional GaN-based LED;

FIGS. 4A to 4D are sectional views sequentially showing a process for explaining the method of manufacturing surface irregularities of the GaN-based LED according to the present invention;

FIG. 5 is a sectional view illustrating the structure of general surface irregularities;

FIG. 6 is a graph showing a change in light extraction efficiency in accordance with the pitch of the surface irregularities;

FIG. 7 is a graph showing a change in light extraction efficiency in accordance with the height of the surface irregularities;

FIG. 8 is a sectional view illustrating the structure of a lateral GaN-based LED to which the surface irregularities manufactured according to the invention are applied; and

FIG. 9 is a sectional view illustrating the structure of a vertical GaN-based LED to which the surface irregularities manufactured according to the invention are applied.

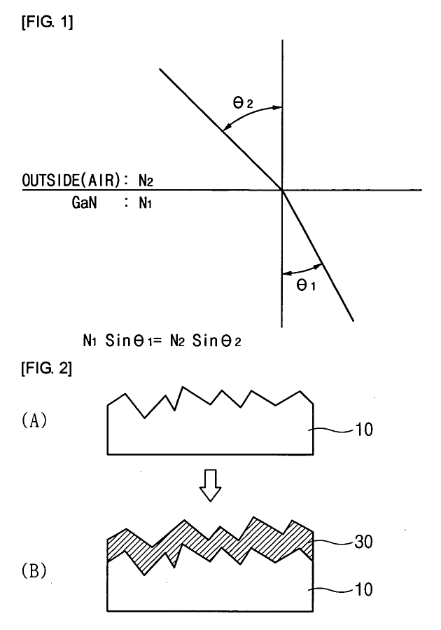

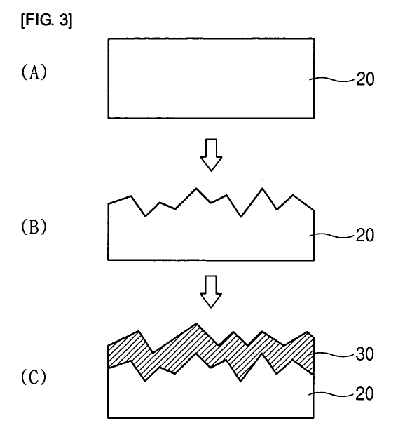

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a method of manufacturing a GaN-based LED according to the present invention will be described in detail with reference to the accompanying drawings.

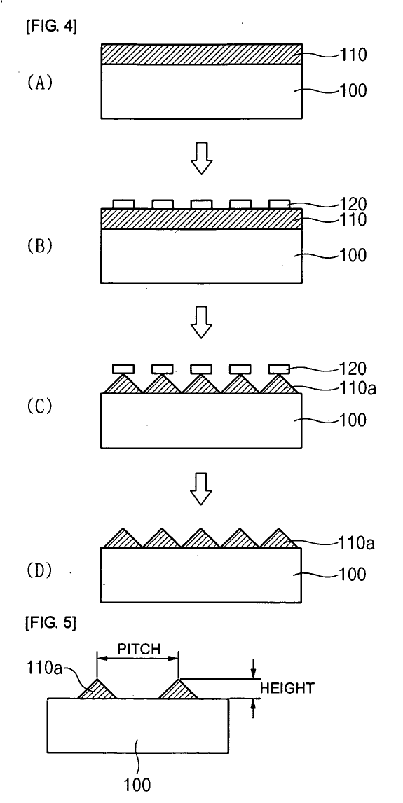

First, a method of manufacturing surface irregularities, which is applied to the method of manufacturing a GaN-based LED according to the invention, will be described with reference to FIG. 4.

FIGS. 4A to 4D are sectional views sequentially showing a process for explaining the method of manufacturing surface irregularities of the GaN-based LED according to the invention.

In the invention, surface irregularities are formed on the surfaces of the p-type and n-type GaN layers, from which light is emitted, compared with the related art where the process of forming surface irregularities is separately performed on the p-type and n-type GaN layers. Therefore, it is possible to simplify the process of forming surface irregularities.

Referring to FIG. 4A, a p-type or n-type GaN layer 100 is first prepared.

Next, an irregularities forming layer 110 is formed on the GaN layer 100. At this time, the irregularities forming layer 100 is preferably formed of a medium which has a similar refractive index to the GaN layer 100 positioned under the irregularities forming layer 100 and can be wet-etched, the medium having a low absorption rate in the visible ray range. In this embodiment, the irregularities forming layer 110 is formed of TiO₂.

As shown in FIG. 4B, a photosensitive film pattern 120 for forming surface irregularities is formed on the irregularities forming layer 110. The photosensitive film pattern 120 can also define a region where an electrode is formed.

As shown in FIG. 4C, the irregularities forming layer 110 is selectively wet-etched with the photosensitive film pattern 120 set to an etching mask, thereby forming surface irregularities 110a on the top surface of the GaN layer 100. At this time, the surface irregularities 110a are preferably formed to have such a pitch and height that light extraction efficiency can be optimalized.

As shown in FIG. 4D, the photosensitive film pattern 120 existing on the surface irregularities 110a is removed.

Hereinafter, such a pitch and height that can optimalize light extraction efficiency will be described in detail with reference to FIGS. 5 to 7.

FIG. 5 is a sectional view illustrating the structure of general surface irregularities, showing that the surface irregularities 110a are formed on the n-type or p-type GaN layer 100 so as to have a uniform pitch and height. The pitch is a distance between the upper ends of the surface irregularities 110a, and the height is a distance from the top surface of the GaN layer 100 to the upper end of the surface irregularities 110a.

Referring to FIG. 6, it can be found that, as the pitch of the surface irregularities 110a is reduced from 8 μm to 2 μm, light extraction efficiency increases from about 17% to about 33%.

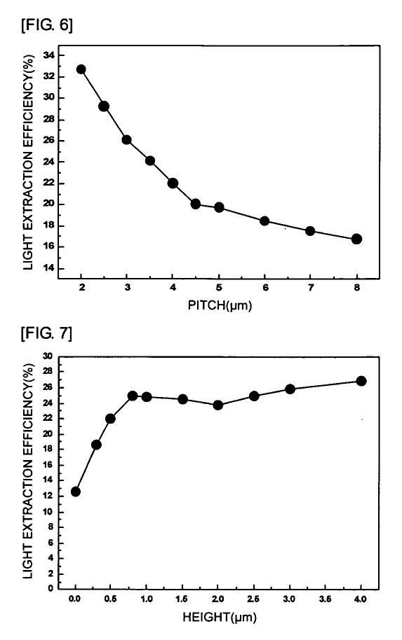

Referring to FIG. 7, it can be found that, as the height of the surface irregularities 110a is increased from 0 μm to 4 μm, light extraction efficiency increases from about 12.5% to about 27%. FIG. 6 is a graph showing a change in light extraction efficiency in accordance with the pitch of the surface irregularities, and FIG. 7 is a graph showing a change in light extraction efficiency in accordance with the height of the surface irregularities.

In other words, as the pitch of the surface irregularities 110a is reduced and the height thereof is increased, the light extraction efficiency of the GaN-based LED including the surface irregularities 110a can be increased.

Meanwhile, in a state where concave and convex portions are defined by a photosensitive film pattern, the irregularities forming layer may be wet-etched using the photosensitive film pattern as an etching mask, thereby forming surface irregularities (refer to FIG. 4). Therefore, the surface irregularities can be formed so as to have such a pitch and height that light extraction efficiency becomes optimal.

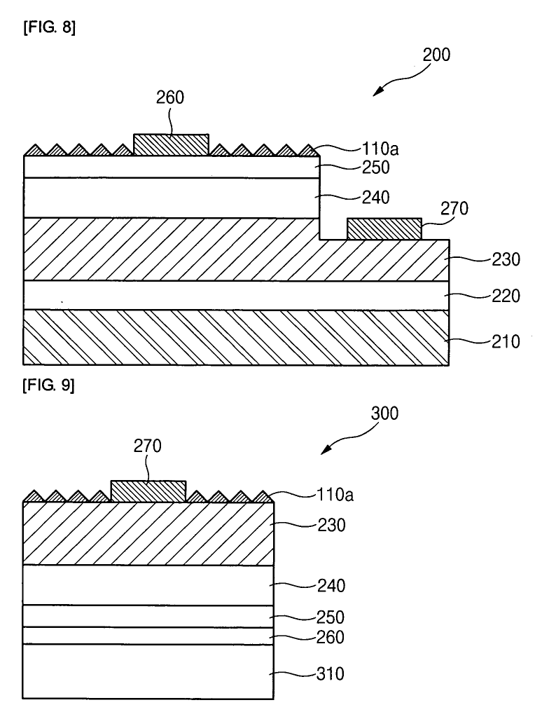

Hereinafter, a GaN-based LED on which the surface irregularities are formed on the p-type or n-type GaN layer by the method of manufacturing surface irregularities according to the invention will be described with reference to FIGS. 8 and 9.

### First Embodiment

First, a GaN-based LED according to a first embodiment of the invention will be described in detail with reference to FIG. 8. FIG. 8 is a sectional view illustrating the structure of a lateral GaN-based LED to which the surface irregularities manufactured according to the invention are applied.

As shown in FIG. 8, the GaN-based LED 200 according to the first embodiment of the invention includes a buffer layer 220, an n-type GaN layer 230, an active layer 240, and a p-type GaN layer 250, which are sequentially laminated on a substrate 210.

Preferably, the substrate 210 is formed of a transparent material including sapphire. Further, the substrate 210 can be formed of zinc oxide (ZnO), gallium nitride (GaN), silicon carbide (SiC) or aluminum nitride (AIN), in addition to sapphire.

The buffer layer 220 is formed of GaN and may be omitted.

The n-type or p-type GaN layer 230 or 250 is formed of a GaN or GaN/AIGaN layer doped with conductive impurities, and the active layer 240 is formed to have a multi-quantum well structure formed of an InGaN/GaN layer.

Portions of the p-type GaN layer 250 and the active layer 240 are removed by mesa-etching such that portions of the n-type GaN layer 230 are exposed.

On the p-type GaN layer 250, the surface irregularities 110a manufactured by the method of manufacturing surface irregularities (refer to FIG. 4) are formed. Preferably, the surface irregularities 110a are formed of TiO₂ having a similar refractive index to the p-type GaN layer 250 and a low absorption rate in the visible ray range. Accordingly, the surface irregularities are preferably formed on a region excluding an electrode formation region which will be described below.

Meanwhile, in this embodiment, there can be provided a current spreading layer (not shown) which is formed of ITO or the like between the p-type GaN layer 250 and the surface irregularities 110a, in order to enhance light extraction efficiency.

On the p-type GaN layer 250 on which the surface irregularities 110a are not formed, a p-electrode 260 is formed. On a predetermined portion of the n-type GaN layer 230 exposed by the mesa-etching, an n-electrode 170 is formed. Preferably, the p-electrode 260 and the n-electrode 270 are formed of Cr/Au so as to serve as a reflecting layer and electrode at the same time.

### Second Embodiment

Referring to FIG. 9, a GaN-based LED according to a second embodiment will be described in detail. FIG. 9 is a sectional view illustrating the structure of a vertical GaN-based LED to which the surface irregularities manufactured according to the invention are applied.

As shown in FIG. 9, the GaN-based LED 300 according to the second embodiment has an n-electrode 270 formed of Cr/Au in the uppermost portion thereof.

Under the n-electrode 270, an n-type GaN layer 230 is formed.

In this embodiment, there can be further provided a current spreading layer (not shown) formed of ITO or the like at the interface between the n-electrode 270 and the n-type GaN layer 230, in order to maximize current spreading efficiency.

On the top surface of the n-type GaN layer 230 on which the n-electrode 270 is not formed, the surface irregularities 110a manufactured by the method of manufacturing surface irregularities (refer to FIGS. 4A to 4D) are formed. Preferably, the surface irregularities 110 are formed of TiO₂ having a similar refractive index to the n-type GaN layer 230 and a low absorption rate in the visible ray range.

Under the n-type GaN layer 230, the active layer 240 and the p-type GaN layer 250 are sequentially laminated.

The n-type or p-type GaN layer 230 or 250 can be formed of a GaN or GaN/AIGaN layer doped with conductive impurities, and the active layer 240 can be formed with a multi-quantum well structure composed of an InGaN/GaN layer.

Under the p-type GaN layer 250, a p-electrode 260 is formed. Although not shown, the p-electrode 260 and a reflecting film (not shown) can be sequentially laminated under the p-type GaN layer 250. When a reflecting film is not provided as in this embodiment, the p-electrode 260 serves as a reflecting film.

Under the p-type electrode 260, a structure support layer 310 is bonded by a conductive bonding layer (not shown). The structure support layer 310 serving as a support layer and electrode of a finalized LED is formed of a silicon substrate, a GaAs substrate, a Ge substrate, or a metallic layer. The metallic layer can be formed through electroplating, electroless plating, thermal evaporation, e-beam evaporation, sputtering, chemical vapor deposition (CVD) or the like.

It has been exemplified in the first embodiment that the surface irregularities manufactured by the method of manufacturing surface irregularities described with reference to FIGS. 4A to 4B are formed on the p-type GaN layer of the lateral GaN-based LED. Further, it is exemplified in the second embodiment that the surface irregularities are formed on the n-type GaN layer of the vertical GaN-based LED.

Although the vertical GaN-based LED is grown on a sapphire substrate, there is a limit in reducing the size of the GaN-based LED so as to reduce a manufacturing cost or improving an optical output or a characteristic of a chip, because such a sapphire substrate is composed of a solid and non-conductive material having poor heat conductivity. Therefore, such a sapphire substrate is removed from the GaN-based LED by a LLO (Laser Lift-Off) process.

As described above, the surface irregularities are formed on the GaN layer by using a medium having a similar refractive index to the GaN layer through a photolithography process. Therefore, the pitch and height of the surface irregularities can be uniformly adjusted into such a condition that light extraction efficiency can be optimalized.

Therefore, it is possible to enhance the external light-emission efficiency and quantum efficiency of the GaN-based LED.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a GaN-based LED comprising:
forming an n-type GaN layer on a substrate;
forming an active layer on the n-type GaN layer;
forming a p-type GaN layer on the active layer;
mesa-etching portions of the p-type GaN layer and the active layer so as to expose a portion of the n-type GaN layer;
forming an irregularities forming layer on the p-type GaN layer;
forming a photosensitive film pattern for forming a surface irregularities pattern on the irregularities forming layer;
selectively wet-etching the irregularities forming layer by using the photosensitive film pattern as an etching mask, thereby forming surface irregularities;
forming a p-electrode on the p-type GaN layer having the surface irregularities formed thereon; and
forming an n-electrode on the exposed n-type GaN layer.

2. The method according to claim 1,
wherein the p-electrode is formed on the p-type GaN layer on which the surface irregularities are not formed.

3. The method according to claim 1 further comprising
forming a current spreading layer on the p-type GaN layer before the forming of the irregularities forming layer.

4. A method of manufacturing a GaN-based LED comprising:
sequentially forming an n-type GaN layer, an active layer, a p-type GaN layer on a substrate, thereby forming a GaN-based LED structure;
forming a p-electrode on the GaN-based LED structure;
bonding a conductive substrate on the p-electrode;
removing the substrate through an LLO process so as to expose the n-type GaN layer;
forming an irregularities forming layer on the n-type GaN layer which is exposed by removing the substrate;
forming a photosensitive film pattern for forming a surface irregularities pattern on the irregularities forming layer;
selectively wet-etching the irregularities forming layer by using the photosensitive film pattern as an etching mask, thereby forming surface irregularities; and
forming an n-electrode on the n-type GaN layer having the surface irregularities formed thereon.

5. The method according to claim 4,
wherein the n-type electrode is formed on the n-type GaN layer on which the surface irregularities are not formed.

6. The method according to claim 4 further comprising
forming a current spreading layer on the n-type GaN layer before the forming of the irregularities forming layer.

7. The method according to claim 4,
wherein the irregularities forming layer is formed of TiO₂.
